(19) United States
(12) Patent Application Publication
(10) Pub. No.: US 2010/0171565 A1
(43) Pub. Date: Jul. 8, 2010

(54) DIVISION CIRCUIT

(76) Inventor: Norihito Okada, Fukushima-Ken (JP)

Correspondence Address: BRINKS HOFER GILSON & LIONE, P.O. BOX 10395, CHICAGO, IL, 60610, US

(21) Appl. No.: 12/619,058

(22) Filed: Nov. 16, 2009

(30) Foreign Application Priority Data
Jan. 7, 2009 (JP) 2009-001651

(51) Int. Cl. H03H 7/46

(52) U.S. Cl. 333/132

(57) ABSTRACT

A division circuit includes: a signal input/output terminal to and from which two signals, that is, a first signal using a first frequency band and a second signal using a second frequency band higher than the first frequency band, are input and output; a first low-pass filter which does not pass the second signal and passes the first signal; a first high-pass filter which is formed such that a plurality of serial resonant circuits set at different resonant frequencies, respectively, is cascaded in parallel and which does not pass the first signal and passes the second signal; and a division point connecting one end of the first low-pass filter to one end of the first high-pass filter between the signal input/output terminal, the first low-pass filter, and the first high-pass filter. In the plurality of series resonant circuits, a first serial resonant circuit is located from the division point.

### CROSS REFERENCE TO RELATED APPLICATION

The present invention contains subject matter related to and claims prior to Japanese Patent Application No. 2009-001651 filed in the Japanese Patent Office on Jan. 7, 2009, the entire contents of which are incorporated herein by reference.

### BACKGROUND

1. Technical Field

The present invention relates to a division circuit, and more particularly, to a division circuit appropriately used when two signals, in which the high-end frequency of one of a frequency band for a digital TV broadcast and a frequency band for the MoCA approaches the low-end frequency of the other thereof, are divided.

2. Related Art

In recent years, home high-speed broadband communication using an existing coaxial cable has been standardized by the MoCA (Multimedia over Coax Alliance) and has been used. Since the coaxial cable used in home high-speed broadband communication is a coaxial cable used in the digital TV broadcast receiver, a division circuit is disposed in the coaxial cable. The division circuit divides signals into the frequency band of a signal (hereinafter, referred to as “a main signal”) transmitted to a digital TV broadcast tuner and the frequency band of a communication signal (hereinafter, referred to as “a MoCA signal”) standardized by the MoCA.

As shown in FIG. 5, a known exemplary division circuit 111 includes a signal input/output terminal 104, a division point 107, a main signal filter circuits 102 and 108, a main signal terminal 105, a MoCA signal filter circuit 103, and a MoCA signal terminal 106. The main signal filter circuits 102 and 108 are connected between the division point 107 and the main signal terminal 105. Since the frequency band of the main signal is set in the range from 54 MHz to 864 MHz, a low-pass filter set in a frequency band of 864 MHz or less and connected to the front stage and a high-pass filter set in a frequency band of 54 MHz or more and connected to the rear stage, for example, are used in the main signal filter circuits 102 and 108.

On the other hand, the MoCA signal filter circuit 103 is connected between the division point 107 and the MoCA signal terminal 106. Since the frequency band of the MoCA signal is set in the range from 1125 MHz to 1525 MHz, a bandpass filter of which the pass band is set in the range from 1125 MHz to 1525 MHz is used in the MoCA signal filter circuit 103, for example.

The low-pass filter, the high-pass filter, and the bandpass filter used in the main signal filter circuits 102 and 108 and the MoCA signal filter circuit 103 are formed such that a plurality of parallel resonant circuits and a plurality of series resonant circuits (not shown) may be cascaded in series or in parallel.

Japanese Unexamined Patent Application Publication No. 2003-69362 is an example of this related art.

In the known division circuit 111, as shown in FIG. 6, the high-end frequency of 864 MHz in the main signal filter circuit 102 and the low-end frequency of 1125 MHz in the MoCA signal filter circuit 103 are distant from each other to some extent. Accordingly, the pass characteristic of the main signal filter circuit 102 does not interfere with the pass characteristic of the MoCA signal filter circuit 103.

However, when the high-end frequency of the main signal filter circuit 102 is changed into 999 MHz to further enlarge the pass band of the main signal filter circuit toward the high end, a problem may arise in that the high-end frequency further approaches the low-end frequency of 1125 MHz of the MoCA signal filter circuit 103 and the pass characteristic of the main signal filter circuit 102 interferes with the pass characteristic of the MoCA signal filter circuit 103.

This interference example is shown in FIG. 7. FIG. 7 is a graph showing the pass characteristics of the main signal filter circuit 102 and the MoCA signal filter circuit 103 after the pass characteristic of the main signal filter circuit 102 is changed in the known division circuit 111 shown in FIG. 5. A curve indicated by a right dotted line in FIG. 7 shows the pass characteristic of the main signal filter circuit 102 before the change. A curve indicated by a solid line shows the pass characteristic of the main signal filter circuit 102 after the change. As shown in FIG. 7, a problem may arise in that a large trap occurs near the low-end frequency 1125 MHz of the MoCA signal filter circuit 103 due to the interference in the known division circuit 111.

Moreover, another problem may arise in that an appropriate attenuation amount cannot be obtained in the frequency equal to or lower than the low-end frequency of the MoCA signal filter circuit 103.

As one cause of the problem, it can be considered that the resonant circuits used in both the main signal filter circuit 102 and the MoCA signal filter circuit 103 have a negative influence on each other.

In the known division circuit 111, a shared low-pass filter is formed by the parallel resonant circuits, like the main signal filter circuit 102, in the MoCA signal filter circuit 103 connected to the rear stage of the division point 107. In this configuration, the pass characteristics of the main signal filter circuit 102 and the MoCA signal filter circuit 103 may also interfere with each other, when the high-end frequency of the main signal filter circuit 102 is changed into 999 MHz.

### SUMMARY

According to a first aspect, a division circuit includes: a signal input/output terminal to and from which two signals, that is, a first signal using a first frequency band and a second signal using a second frequency band higher than the first frequency band, are input and output; a first low-pass filter which does not pass the second signal and passes the first signal; a first high-pass filter which is formed such that a plurality of serial resonant circuits set at different resonant frequencies, respectively, is cascaded in parallel and which does not pass the first signal and passes the second signal; and a division point connecting one end of the first low-pass filter to one end of the first high-pass filter between the signal input/output terminal, the first low-pass filter, and the first high-pass filter. In the plurality of series resonant circuits, a first serial resonant circuit using a frequency which is closest to a high-end frequency of the first frequency band as a resonant frequency is located from the division point so as to be distant by at least one of the series resonant circuits other than the first series resonant circuit.

In the division circuit according to the first aspect of the invention, the first high-pass filter is formed such that the plurality of series resonant circuits is connected in parallel without using the parallel resonant circuits. In addition, in the first low-pass filter, the first series resonant circuit is connected through the other series resonant circuits. Accordingly, it is possible to inhibit the pass characteristic near the high-end frequency of the first low-pass filter from deteriorating, owing to the pass characteristic of the first high-pass filter.

According to a second aspect, in the division circuit, a second series resonant circuit using a frequency which is farthest from a high-end frequency of the first frequency band as a resonant frequency may be connected at the initial position in the plurality of series resonant circuits.

### BRIEF DESCRIPTION OF THE DRAWINGS

FIG. 1 is a block diagram illustrating an intermediate frequency circuit and a division circuit according to an embodiment.

FIG. 2 is an equivalent circuit diagram illustrating the intermediate frequency circuit and the division circuit according to the embodiment.

FIG. 3 is a graph showing pass characteristics of filter circuits in the division circuit according to the embodiment.

FIG. 4 is a graph showing the pass characteristics of the filter circuits depending on whether a peaking circuit exists in the intermediate frequency circuit according to the embodiment.

FIG. 5 is a block diagram illustrating an example of a known division circuit.

FIG. 6 is a graph showing the pass characteristics of filter circuits in the known division circuit.

FIG. 7 is a graph showing the pass characteristics of a main signal filter circuit and a MoCA signal filter circuit, when a pass band of the main signal filter circuit approaches the pass band of the MoCA signal filter circuit due to design change of the main signal filter circuit in the known division circuit.

### DESCRIPTION OF EXEMPLARY EMBODIMENTS

Hereinafter, a division according to an embodiment of the invention will be described.

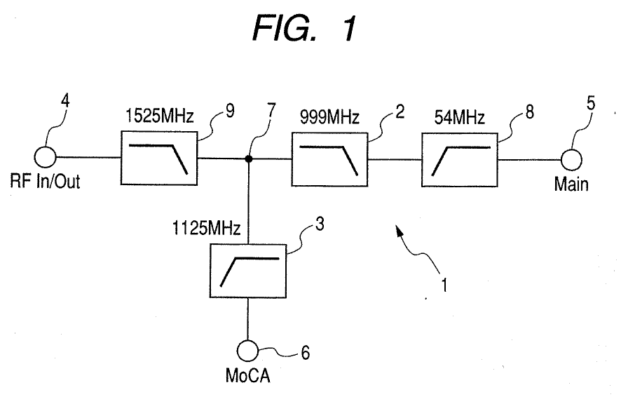

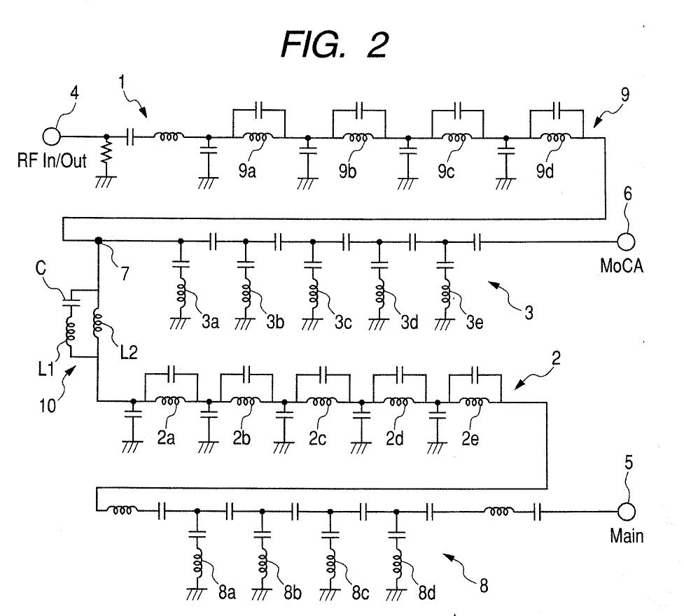

FIG. 1 is a block diagram illustrating a division circuit 1 according to this embodiment. FIG. 2 is a circuit diagram illustrating the division circuit 1 according to this embodiment. As shown in FIGS. 1 and 2, the division circuit 1 according to this embodiment includes a peaking circuit 10, a second low-pass filter 9, a signal input/output terminal 4, a division point 7, a first low-pass filter 2, and a first high-pass filter 3.

The signal in/out terminal 4 is a terminal to and from which at least two signals, a main signal and a MoCA signal, are input and output, as shown in FIGS. 1 and 2. The main signal is selected as a first signal. The frequency band of the main signal serving as a first frequency band is in the range from 54 MHz to 999 MHz. The MoCA signal is selected as a second signal. The frequency band of the MoCA signal serving as the second frequency band is higher than the frequency band of the main signal and is in the range from 1125 MHz to 1525 MHz.

As shown in FIGS. 1 and 2, the division point 7 is a connection point connecting one end of the first low-pass filter 2 to one end of the first high-pass filter 3 between the signal input/output terminal 4, the first low-pass filter 2, and the first high-pass filter 3. The other end of the first low-pass filter 2 is connected to a main signal terminal 5 and the other end of the first high-pass filter 3 is connected to a MoCA signal terminal 6.

As shown in FIG. 1, a pass band of the first low-pass filter 2 is set to a frequency band which does not pass the MoCA signal and passes the main signal. That is, 999 MHz is set as a high-end frequency. As shown in FIG. 2, the first low-pass filter 2 is formed such that five parallel resonant circuits 2a to 2e set at different resonant frequencies, respectively, are cascaded in series. The parallel resonant circuit (for example, the parallel resonant circuit 2a) is a circuit having connection ends which are both ends of a capacitor and an inductor connected in parallel.

Among the five parallel resonant circuits 2a to 2e, the first parallel resonant circuit 2e serves as a parallel resonant circuit having a resonant frequency of 1125 MHz which is closest to the high-end frequency (999 MHz) of the frequency band of the main signal. The first parallel resonant circuit 2e is located from the division point 7 so as to be distant by at least one of the parallel resonant circuits (for example, the parallel resonant circuit 2a) other than the first parallel resonant circuit 2e. As shown in FIG. 2, it is desirable that the first parallel resonant circuit 2e is connected at the last position in the parallel resonant circuits. The second parallel resonant circuit 2a serves as a parallel resonant circuit having a resonant frequency of 1.5 GHz which is farthest from the high-end frequency (999 MHz) of the frequency band of the main signal. It is desirable that the second parallel resonant circuit 2a is connected at the initial position in the five parallel resonant circuits 2a to 2e.

A second high-pass filter 8 of which the pass band is the frequency band of 54 MHz or more may be connected to the rear of the five parallel resonant circuits 2a to 2e. The second high-pass filter 8 is formed such that four serial resonant circuits 8a to 8d are cascaded in series. The serial resonant circuit (for example, the serial resonant circuit 8a) has a connection end which is one end of a capacitor and an inductor connected in series and the other end connected to the ground.

As shown in FIG. 1, the pass band of the first high-pass filter 3 is set to a frequency band which does not pass the main signal and passes the MoCA signal, that is, to a frequency band of 1125 MHz or more. As shown in FIG. 2, the first high-pass filter 3 is formed such that five series resonant circuits 3a to 3e set at different resonant frequencies, respectively, are cascaded in parallel. The parallel resonant circuit (for example, the series resonant circuit 3a) is a circuit having a connection end which is one end of a capacitor and an inductor connected in series and the other end connected to the ground.

Among the five series resonant circuits 3a to 3e, the first series resonant circuit 3e serves as a series resonant circuit having a resonant frequency of 999 MHz which is closest to the low-end frequency (1125 MHz) of the frequency band of the MoCA signal. The first series resonant circuit 3e is located from the division point 7 so as to be distant by at least one of the series resonant circuits other than the first series resonant circuit 3e. It is desirable that the first series resonant circuit 3e is connected at the last position in the five series resonant circuits 3a to 3e. The second series resonant circuit 3a serves as a series resonant circuit having a resonant frequency of 2 GHz which is farthest from the low-end frequency (1125 MHz) of the frequency band of the MoCA signal. It is desirable that the second series resonant circuit 3a is connected at the initial position in the five series resonant circuits 3a to 3e.

No parallel resonant circuit is connected to the first high-pass filter 3.

The peaking circuit 10 is connected between the division point 7 and one end of the first low-pass filter 2. The peaking circuit 10 is formed such that a composite element constituted by a capacitor C and a first inductor L1 connected in series and a second inductor L2 are connected in parallel. The resonant frequency of the peaking circuit 10 is near the low-end frequency (1125 MHz) of the frequency band of the MoCA signal and is set to a frequency of 1.2 GHz which is the low-end frequency (1125 MHz) or more in the frequency band of the MoCA signal.

As shown in FIG. 1, the second low-pass filter 9 serving as a third filter circuit is connected between the signal input/output terminal 4 and the division point 7. A pass band of the second low-pass filter 9 is set to a frequency band passing the MoCA signal and the main signal, that is, to a frequency band of 1525 MHz or less. As shown in FIG. 2, the second low-pass filter 9 is formed such that four parallel resonant circuits 9a to 9d set at different resonant frequencies, respectively, are cascaded in series. The parallel resonant circuit (for example, the parallel resonant circuit 9a) is a circuit having connection ends which are both ends of a capacitor and an inductor connected in parallel.

Next, the operation of the division circuit 1 according to this embodiment will be described.

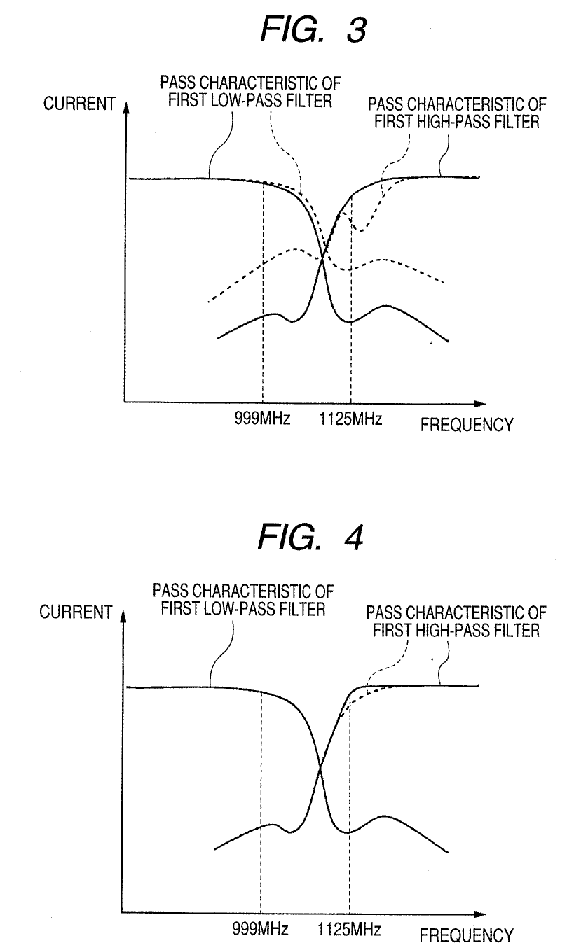

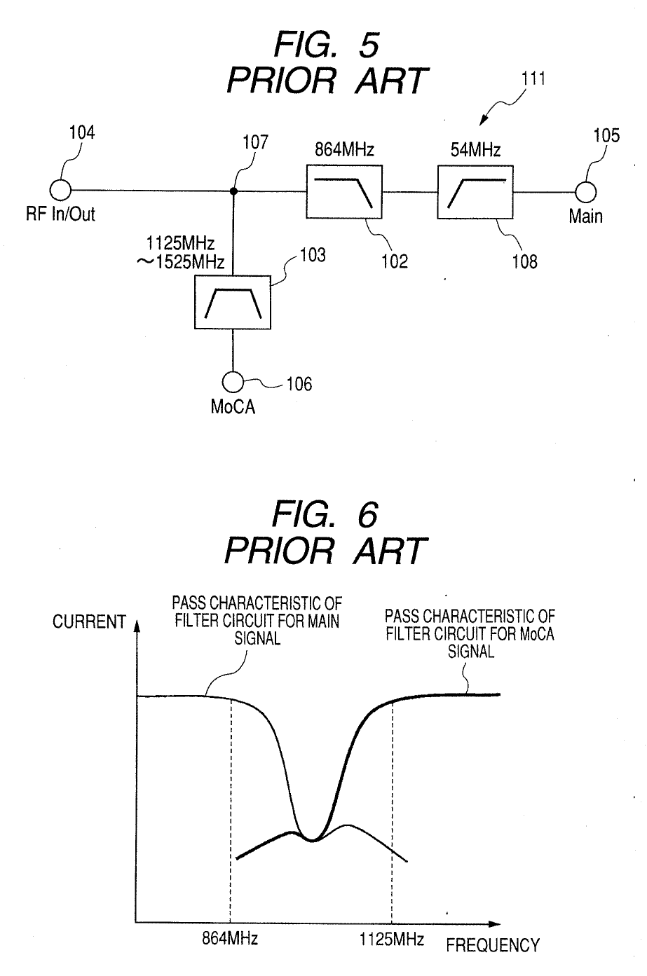

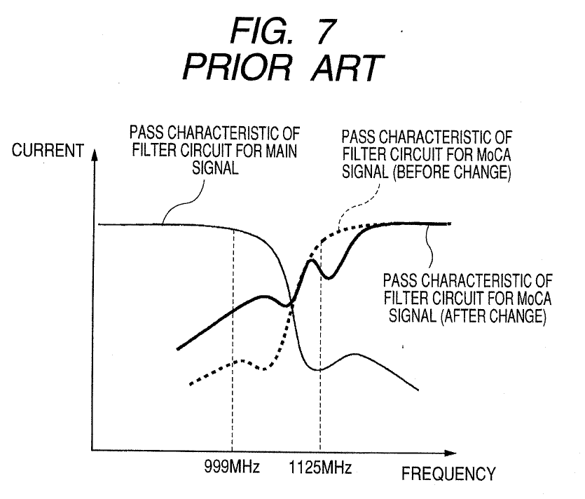

FIG. 3 is a graph showing the pass characteristics of filter circuits in the division circuit 1 according to this embodiment. In FIG. 3, two curves indicated by dotted lines show the pass characteristics in a known circuit in FIG. 5. Two curves indicated by solid lines show the pass characteristics of the first low-pass filter 2 and the first high-pass filter 3 according to this embodiment in FIG. 1.

In the division circuit 1 according to this embodiment, as shown in FIG. 2, the first high-pass filter 3 is formed such that the five series resonant circuits 3a to 3e are sequentially connected in series from the division point 7 to the MoCA signal terminal 6. In the first high-pass filter 3, no parallel resonant circuit is used. Among the five series resonant circuits 3a to 3e, the first series resonant circuit 3e using the frequency (999 MHz) which is near the high-end frequency of the main signal as a resonant frequency is connected to the first low-pass filter 2 via another series resonant circuit (for example, the series resonant circuit 3a). With such a configuration, the curve indicated by the left dotted line in FIG. 3 is transferred to the curve indicated by the solid line in the pass characteristic of the first low-pass filter 2, and the pass characteristic near the high-end frequency in the first low-pass filter 2 can be inhibited from deteriorating owing to the pass characteristic of the first high-pass filter 3. Therefore, it is possible to appropriately set the attenuation amounts of the first low-pass filter 2 and the first high-pass filter 3 without interfering with the pass characteristics of the first low-pass filter 2 and the first high-pass filter 3.

As the connection position of the first series resonant circuit 3e in the five series resonant circuits 3a to 3e moves to the MoCA signal terminal 6, the pass characteristic of the first low-pass filter 2 is less likely to deteriorate. For this reason, when the first series resonant circuit 3e is connected at the last position, the pass characteristic near the high-end frequency in the first low-pass filter 2 can effectively be inhibited from deteriorating owing to the pass characteristic of the first high-pass filter 3.

In contrast, the second series resonant circuit 3a using the frequency of 2 GHz which is farthest from the high-end frequency (999 MHz) of the main signal as the resonant frequency is connected at the initial position in the five series resonant circuits 3a to 3e. However, since the resonant frequency is distant from the high-end frequency (999 MHz) of the main signal, the pass characteristic of the first low-pass filter 2 is less likely to deteriorate. Accordingly, when the second series resonant circuit 3a is connected at the initial position in the five series resonant circuits 3a to 3e, the pass characteristic near the high-end frequency can be inhibited from deteriorating without having a bad influence on the pass characteristic of the first low-pass filter 2 in the relation of the connection position with the first series resonant circuit 3e.

In the division circuit 1 according to this embodiment, the first low-pass filter 2 is formed such that the five parallel circuits 2a to 2e are sequentially connected in series from the division point 7 toward the main signal terminal 5. Unlike the first high-pass filter 3, the second high-pass filter 8 including the four series resonant circuits 8a to 8d may be connected to the rear side of the first low-pass filter 2. Among the five parallel resonant circuits 2a to 2e, the first parallel resonant circuit 2e using the low-end frequency (1125 MHz) of the frequency band of the MoCA signal, which is closest to the high-end frequency of 999 MHz of the first low-pass filter 2, as the resonant frequency is connected to the first high-pass filter 3 via another parallel resonant circuit (for example the parallel resonant circuit 2a). With such a configuration, the curve indicated by the right dotted line in FIG. 3 is transferred to the curve indicated by the solid line in the pass characteristic of the first high-pass filter 3, and the pass characteristic near the low-end frequency in the first high-pass filter 3 can be inhibited from deteriorating owing to the pass characteristic of the first low-pass filter 2. Therefore, it is possible to appropriately set the attenuation amounts of the first low-pass filter 2 and the first high-pass filter 3 without interfering with the pass characteristics of the first low-pass filter 2 and the first high-pass filter 3.

As the connection position of the first parallel resonant circuit 2e moves to the last position, the pass characteristic of the first high-pass filter 3 is less likely to deteriorate. For this reason, when the first parallel resonant circuit 2e is connected at the last position, the pass characteristic near the low-end frequency in the first high-pass filter 3 can effectively be inhibited from deteriorating owing to the pass characteristic of the first low-pass filter 2.

In contrast, the second parallel resonant circuit 2a using the frequency which is farthest from the low-end frequency (1125 MHz) of the frequency band of the MoCA signal as the resonant frequency is connected at the initial position in the five parallel resonant circuits 2a to 2e. However, since the resonant frequency is distant from the low-end frequency (1125 MHz) of the MoCA signal, the pass characteristic of the first high-pass filter 3 is less likely to deteriorate. Accordingly, when the second parallel resonant circuit 2a is connected at the initial position in the five parallel resonant circuits 2a to 2e, the pass characteristic near the low-end frequency can be inhibited from deteriorating without having a bad influence on the pass characteristic of the first high-pass filter 3 in the relation of the connection position with the first parallel resonant circuit 2e.

In the division circuit 1 according to this embodiment, as shown in FIGS. 1 and 2, the peaking circuit 10 is connected between the division point 7 and the first low-pass filter 2. Since the resonant frequency of the peaking circuit 10 is near the low-end frequency (1125 MHz) of the frequency band of the MoCA signal and is set as a frequency higher than the low-end frequency (1125 MHz), the pass characteristic of the low-end frequency (1125 MHz) is improved. Accordingly, as shown in FIG. 4, the pass characteristic of the first high-pass filter 3 deteriorating due to an increase in the number of other series resonant circuits (for example, the series resonant circuit 3a and the like) connected to the front of the first series resonant circuit 3e can be improved from the curve indicated by the right dotted line up to the curve indicated by the right solid line in FIG. 4.

In the division circuit 1 according to this embodiment, as shown in FIGS. 1 and 2, the second low-pass filter 9 is connected. The second low-pass filter 9 is formed such that the four parallel resonant circuits 9a to 9d are cascaded in series and is connected between the signal input/output terminal 4 and the division point 7, which are connected at the front stage of the first high-pass filter 3 and the first low-pass filter 2. With such a configuration, even though the parallel resonant circuits 9a to 9d are used, the parallel resonant circuits 9a to 9d can pass a signal contained in the pass band of the second low-pass filter 9 without having a bad influence on the first high-pass filter 3 or the first low-pass filter 2.

In the division circuit 1 according to this embodiment, the pass characteristic in the cutoff frequency on the upper side of the first low-pass filter 2 and the pass characteristic in the cutoff frequency on the lower side of the first high-pass filter 3 are inhibited from deteriorating, even when the cutoff frequencies of the two filter circuits 2 and 3 are close to each other. Accordingly, it is possible to obtain the advantage of appropriately setting the attenuation amounts without interfering with the pass characteristics of the first low-pass filter 2 and the first high-pass filter 3.

The invention is not limited to the above-described embodiment, but may be modified in various forms, if necessary.

It should be understood by those skilled in the art that various modifications, combinations, sub-combinations and alterations may occur depending on design requirements and other factors insofar as they are within the scope of the appended claims of the equivalents thereof.

What is claimed is:

1. A division circuit comprising:
a signal input/output terminal to and from which a first signal using a first frequency band and a second signal using a second frequency band higher than the first frequency band, are input and output;
a first low-pass filter which does not pass the second signal and passes the first signal;
a first high-pass filter which is configured such that a plurality of serial resonant circuits set at different resonant frequencies, respectively, is cascaded in parallel and which does not pass the first signal and passes the second signal; and
a division point connecting one end of the first low-pass filter to one end of the first high-pass filter between the signal input/output terminal, the first low-pass filter, and the first high-pass filter;
wherein in the plurality of series resonant circuits, a first serial resonant circuit using a frequency which is closest to a high-end frequency of the first frequency band as a resonant frequency is located from the division point so as to be distant by at least one of the series resonant circuits other than the first series resonant circuit.

2. The division circuit according to claim 1, wherein in the plurality of series resonant circuits, a second series resonant circuit using a frequency which is farthest from a high-end frequency of the first frequency band as a resonant frequency is connected at the initial position in the plurality of series resonant circuits.

3. The division circuit according to claim 1, wherein the first series resonant circuit is connected at the last position in the plurality of series resonant circuits.

4. The division circuit according to claim 1,
wherein the first low-pass filter is configured such that a plurality of parallel resonant circuits set at different resonant frequencies, respectively, is cascaded in series, and
wherein in the plurality of parallel resonant circuits, a first parallel resonant circuit using a frequency which is closest to a low-end frequency of the second frequency band as a resonant frequency is located from the division point so as to be distant by at least one of the parallel resonant circuits other than the first parallel resonant circuit.

5. The division circuit according to claim 4, wherein in the plurality of parallel resonant circuits, a second parallel resonant circuit using a frequency which is farthest from a low-end frequency of the second frequency band as a resonant frequency is connected at the initial position in the plurality of parallel resonant circuits.

6. The division circuit according to claim 4, wherein the first parallel resonant circuit is connected at the last position in the plurality of parallel resonant circuits.

7. The division circuit according to claim 1, further comprising a peaking circuit connected between the division point and one end of the first low-pass filter and using a frequency, which is near a low-end frequency of the second frequency band and higher than the low-end frequency of the second frequency band, as a resonant frequency.

8. The division circuit according to claim 1, further comprising a second low-pass filter which is formed such that a plurality of parallel resonant circuits set at different resonant frequencies, respectively, is cascaded in series between the signal input/output terminal and the division point and which passes the first and second signals.
